(19) United States
(12) Patent Application Publication
(10) Pub. No.: US 2026/0231810 A1
(43) Pub. Date: Aug. 6, 2026

(54) METHOD FOR PRODUCING A SEMICONDUCTOR MODULE ARRANGEMENT

(71) Applicant: Infineon Technologies AG, Neubiberg (DE)

(72) Inventors: Arthur Unrau, Geseke (DE); Olaf Rüdiger Hohlfeld, Warstein / Suttrop (DE); Adrian Lis, Regensburg (DE)

(21) Appl. No.: 19/530,957

(22) Filed: Feb. 5, 2026

(30) Foreign Application Priority Data
Feb. 6, 2025 (DE) 102025104341.8

(51) Int. Cl. H10W 74/01

(52) U.S. Cl. CPC H10W 74/016

(57) ABSTRACT

A method for producing a semiconductor module arrangement includes: arranging a molding tool vertically above a substrate of the semiconductor module arrangement, a plurality of pins and/or rivets being arranged on the substrate, each pin and/or rivet having essentially the same height in a vertical direction perpendicular to the substrate, the molding tool including a first subset and a second subset of cover elements, each cover element of the first subset being arranged vertically above a different one of the pins and/or rivets, the cover elements of the second subset not being arranged vertically above any pin or rivet; pressing each cover element of the first subset on the respective pin or rivet; and pouring a first material on the substrate. The first material is prevented from covering a top surface of each of the pins and/or rivets by the respective cover elements of the first subset.

### TECHNICAL FIELD

The instant disclosure relates to methods for producing a semiconductor module arrangement.

### BACKGROUND

Semiconductor module arrangements often include at least one substrate arranged in a housing. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. A semiconductor module arrangement generally comprises a plurality of terminal elements electrically connected to the first metallization layer with a first end to provide an electrical connection between the inside and the outside of the housing. Conventional semiconductor module arrangements often further include a casting compound which may at least partly fill the interior of the housing, thereby covering at least some of the components and electrical connections that are arranged on the substrate. The terminal elements may be partly embedded in the casting compound. At least their second ends, however, are not covered by the casting compound and protrude from the casting compound such that they can be electrically contacted.

Different semiconductor module arrangements often have different layouts. That is, the different components, including the terminal elements, are arranged at different positions on a substrate. When forming the casting compound, it needs to be ensured that the second ends of the terminal elements are not covered by the casting compound. In some semiconductor module arrangements, terminal elements are inserted into rivets which are attached to the substrate. In such cases, when forming the casting compound, it needs to be ensured that those ends of the rivets which are facing away from the substrate are not covered by the casting compound such that the terminal elements can be easily inserted and an adequate electrical contact between the terminal elements and the respective rivet is provided. As the layout between different semiconductor modules may differ, special molding tools may be required in order to match the respective layout. This is cumbersome and cost-intensive.

There is a need for a method for forming a semiconductor module arrangement, which allows to produce semiconductor module arrangements having different layouts efficiently and at low costs.

### SUMMARY

A method for producing a semiconductor module arrangement includes arranging a molding tool vertically above a substrate of the semiconductor module arrangement, wherein a plurality of pins and/or rivets is arranged on the substrate, wherein each of the plurality of pins and/or rivets has essentially the same height in a vertical direction perpendicular to the substrate, wherein the molding tool includes a plurality of cover elements, the plurality of cover elements including a first subset of cover elements and a second subset of cover elements, wherein each cover element of the first subset of cover elements is arranged vertically above a different one of the plurality of pins and/or rivets, and wherein the cover elements of the second subset of cover elements are not arranged vertically above any pin or rivet, pressing each cover element of the first subset of cover elements on the respective pin or rivet, and pouring a first material on the substrate, thereby covering the substrate and enclosing each of the plurality of pins and/or rivets, wherein the first material is prevented from covering a top surface of each of the plurality of pins and/or rivets by means of the respective cover elements of the first subset of cover elements.

The invention may be better understood with reference to the following drawings and the description. The components in the figures are not necessarily to scale, emphasis instead being placed upon illustrating the principles of the invention.

Moreover, in the figures, like referenced numerals designate corresponding parts throughout the different views.

### BRIEF DESCRIPTION OF THE DRAWINGS

FIG. 1 is a cross-sectional view of a power semiconductor module arrangement.

FIG. 2 is a three-dimensional view of a power semiconductor module arrangement arranged in a housing.

FIGS. 3 and 4 schematically illustrate steps of a method for producing a semiconductor module arrangement according to embodiments of the disclosure.

FIG. 5 is a three-dimensional view of a pressing tool used for performing the method according to embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

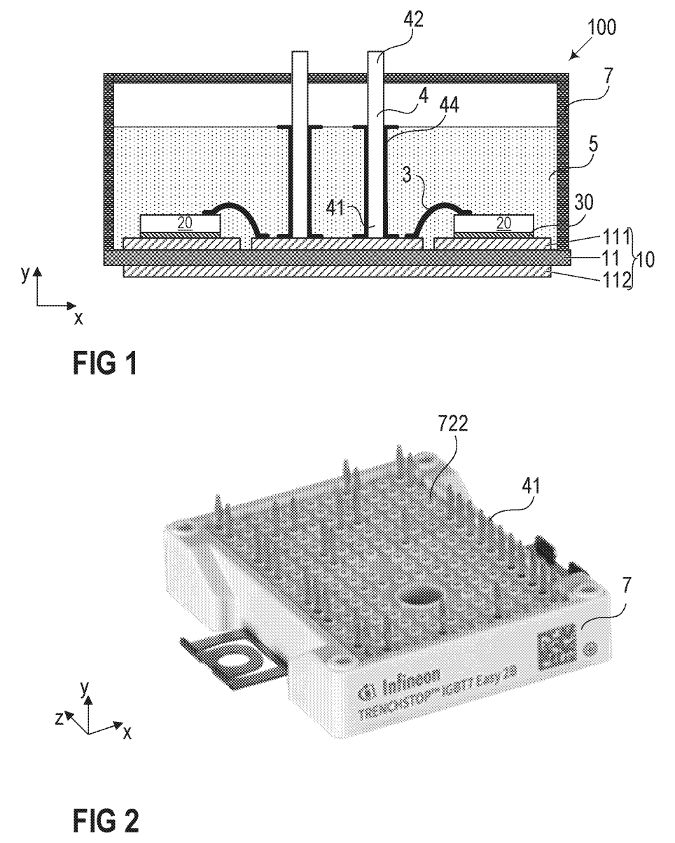

Referring to FIG. 1, a cross-sectional view of a semiconductor module arrangement 100 is illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1µm and about 50µm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 forms a ground surface of the housing 7, while the housing 7 itself solely comprises sidewalls and (optionally) a cover. This, however, is only an example. It is also possible that the housing 7 further comprises a base surface and the substrate 10 be arranged inside the housing 7 and on the base surface. According to another example, the substrate 10 may be mounted on a base plate (not illustrated). In some power semiconductor module arrangements 100, more than one substrate 10 is arranged on a single base plate. The base plate may form a base surface of the housing 7, for example.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes three different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module arrangement 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second ends 42. The terminal elements 4 illustrated in FIG. 1, however, are only examples. Terminal elements 4 may be implemented in any other way and may be arranged anywhere within the housing 7. For example, one or more terminal elements 4 may be arranged close to or adjacent to the sidewalls of the housing 7. Any other suitable implementation is possible.

In the semiconductor module arrangement 100 illustrated in FIG. 1, the first end 41 of each terminal element 4 is inserted into a rivet 44. A first end of each of the rivets 44 is attached to the substrate 10, i.e. to the first metallization layer 111. The rivets 44 may be electrically and mechanically connected to the substrate 10 by an electrically conductive connection layer (not specifically illustrated for the rivets 44 in FIG. 1), for example. Such an electrically conductive connection layer may be a solder layer, a layer of an electrically conductive adhesive, or a layer of a sintered metal powder, e.g., a sintered silver powder, for example. A second end of the rivets 44 faces away from the substrate 10. The terminal elements 4 are inserted into the rivets 44 from their respective second ends. It is, however, generally also possible that a terminal element 4 is directly connected to the substrate 10 by means of an electrically conductive connection layer. That is, the rivets 44 can also be omitted.

Conventional semiconductor module arrangements 100 generally further include a casting compound 5. The casting compound 5 may consist of or include a silicone gel or may be a rigid molding compound, for example. The casting compound 5 may at least partly fill the interior of the housing 7, thereby covering the components and electrical connections that are arranged on the substrate 10. The rivets 44 may be embedded in the casting compound 5. However, at least their second ends facing away from the substrate 10 are not covered by the casting compound 5 such that they are freely accessible for the terminal elements 4. If terminal elements 4 are directly connected to the substrate 10 without rivets 44, the terminal elements 4 may be at least partly embedded in the casting compound 5. At least a surface of each terminal element 4 facing away from the substrate, however, is not covered by the casting compound 5 such that it can be electrically contacted.

The casting compound 5 is configured to protect the components and electrical connections inside the semiconductor module 100, in particular inside the housing 7, from certain environmental conditions and mechanical damage. The casting compound 5 further provides for an electrical isolation of the components inside the housing 7. If the casting compound 5 is a rigid molding compound, the housing 7 can also be omitted.

The casting compound 5 may form a protective layer in a vertical direction y of the substrate 10. The vertical direction y is a direction that is essentially perpendicular to a top surface of the substrate 10. The top surface of the substrate 10 is a surface on which semiconductor bodies 20 are or may be mounted. The casting compound 5 at least partly covers any components that are arranged on the top surface of the substrate 10 as well as any exposed surfaces of the substrate 10.

FIG. 2 schematically illustrates a semiconductor module with a plurality of terminal elements 4 (second ends 42 of terminal elements) protruding out of the cover of a housing 7. The cover in this example comprises a plurality of openings 722. Terminal elements 4 protrude out of some but not all of the openings 722. By providing a plurality of openings 722 in the lid, one and the same housing 7 can be used for many different layouts or applications without the need for customizing the housing 7 for specific applications or customers.

The casting compound 5 is usually formed by filling a first material into the housing 7, and subsequently curing the first material. When filling the first material into the housing 7, it needs to be ensured that at least a top surface of the terminal elements 4 and/or a top surface of the rivets 44 arranged on the substrate 10 remains free of the first material. When using rivets 44 as illustrated in FIG. 1, in particular, it needs to be ensured that the first material does not flow inside the rivets 44. In this way, the second ends of the rivets 44 remain open and are freely accessible by the terminal elements 4. Further, an adequate electrical contact is ensured between the rivets 44 and the respective terminal elements 4, which is not disrupted by the first material. If terminal elements 4 are directly attached to the substrate 10, at least their second ends 42 should remain free of first material such that the can be electrically contacted.

Respective tools can be used when filling the first material into the housing 7 which cover at least a surface of the rivets 44 and/or terminal elements 4 which faces away from the substrate 10. However, as mentioned above, many different layouts are possible for different semiconductor module arrangements. That is, the rivets 44 and/or terminal elements 4 may be arranged at different positions on the substrate 10 in different semiconductor module arrangements. Consequently, respective customized tools may be required in order to match each and every respective layout. This is cumbersome and cost-intensive.

Terminal elements 4 are often implemented as simple pins. Therefore, terminal elements 4 will also be referred to as pins 4 in the following. A semiconductor module arrangement may only comprise terminal elements 4 that are directly coupled to the substrate 10 by means of electrically conductive connection layers. Alternatively, a semiconductor substrate arrangement may only comprise terminal elements 4 that are connected to the substrate 10 by means of rivets 44, as schematically illustrated in the figures. It is, however, also possible that some terminal elements 4 are directly coupled to the substrate 10 by means of electrically conductive connection layers, while other terminal elements 4 are connected to the substrate 10 by means of rivets 44.

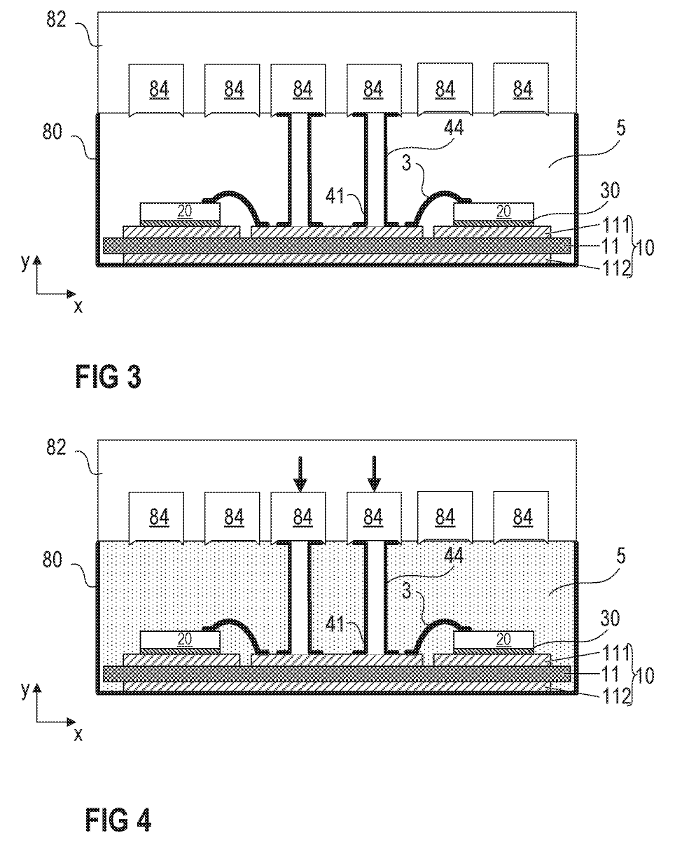

A method for producing a semiconductor module arrangement according to embodiments of the disclosure comprises arranging a molding tool 82 vertically above a substrate 10 of the semiconductor module arrangement, wherein a plurality of pins 4 and/or rivets 44 is arranged on the substrate 10, wherein each of the plurality of pins 4 and/or rivets 44 has essentially the same height in a vertical direction y perpendicular to the substrate 10, wherein the molding tool 82 comprises a plurality of cover elements 84, the plurality of cover elements 84 comprising a first subset of cover elements 84 and a second subset of cover elements 84, wherein each cover element 84 of the first subset of cover elements 84 is arranged vertically above a different one of the plurality of pins 4 and/or rivets 44, and wherein the cover elements 84 of the second subset of cover elements 84 are not arranged vertically above any pin 4 or rivet 44. This is schematically illustrated in FIG. 3.

Now referring to FIG. 4, the method further comprises pressing each cover element 84 of the first subset of cover elements 84 on the respective pin 4 or rivet 44, and pouring a first material on the substrate 10, thereby covering the substrate 10 and enclosing each of the plurality of pins 4 and/or rivets 44, wherein the first material is prevented from covering a top surface of each of the plurality of pins 4 and/or rivets 44 by means of the respective cover elements 84 of the first subset of cover elements 84.

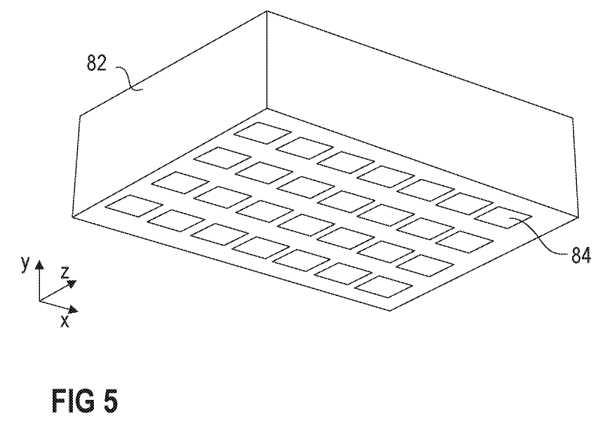

As is schematically illustrated in FIGS. 3 and 4 as well as in the three-dimensional view of a molding tool 82 of FIG. 5, the number of cover elements 84 included in the plurality of cover elements 84 is greater than the number of pins 4 and/or rivets 44 on the substrate 10. The cover elements 84 may be arranged in a regular pattern on a side of the molding tool 82 which, when the molding tool 82 is arranged above the substrate 10, faces towards the substrate 10. For example, the cover elements 84 may be arranged in rows and columns. A cross-sectional area of a surface of the molding tool 82 facing towards the substrate 10 may essentially equal a cross-sectional area of the substrate 10, for example. It is, however, also possible that a cross-sectional area of a surface of the molding tool 82 facing towards the substrate 10 is greater than a cross-sectional area of the substrate 10, for example. According to some examples, the molding tool 82 may have essentially the same shape and size as the substrate 10. The cover elements 84 may be evenly distributed over the surface of the molding tool 82 facing towards the substrate 10. In this way, the molding tool 82 can be used for many different semiconductor module layouts. Irrespective of where the pins 4 and/or rivets 44 are arranged on the substrate 10, there is always one of the cover elements 84 arranged above each of the pins 4 and/or rivets 44. In this way, customized molding tools which can only be used for very specific layouts become superfluous.

According to some embodiments, pressing each cover element 84 of the first subset of cover elements 84 on the respective pin 4 or rivet 44 comprises moving the molding tool 82 together with the plurality of cover elements 84 towards the substrate 10. The cover elements 84 may be connected to the molding tool 82 by means of a spring connection, for example. When the molding tool 82 is moved towards the substrate 10, the cover elements 84 of the first subset contact the pins 4 or rivets 44. As the molding tool 82 is moved further towards the substrate 10, the cover elements 84 of the first subset will give in to a certain degree, due to the spring connection. In this way, they can be firmly pressed onto the respective pins 4 and/or rivets 44 without damaging the pins 4 and/or rivets 44.

Alternatively, pressing each cover element 84 of the first subset of cover elements 84 on the respective pin 4 or rivet 44 comprises individually moving the cover elements 84 of the first subset towards the substrate 10. That is, the cover elements 84 may be movable with respect to the molding tool 82. For example, each cover element 84 may be movable individually with respect to the molding tool 82 by means of a moving mechanism. The molding tool 82 may first be moved towards the substrate 10 until the cover elements 84 of the first subset contact the respective pins 4 or rivets 44. The molding tool 82 may then remain in this position. The cover elements 84 of the first subset, however, may be moved further towards the substrate 10, e.g., by means of the moving mechanism. In this alternative way, the cover elements 84 of the first subset can also be firmly pressed onto the respective pins 4 and/or rivets 44 without damaging the pins 4 and/or rivets 44.

Once the first material has been poured onto the substrate 10, a curing step may follow, thereby forming a casting compound. The molding tool 82 may be removed after the first material has been poured onto the substrate 10. The molding tool 82 may be removed before or after curing the first material. If the molding tool 82, during a curing step, remains in its position with the cover elements 84 of the first subset firmly pressed against the pins 4 and/or rivets 44, it may be ensured that the first material does not reach a top surface of the pins 4 and/or rivets 44 facing away from the substrate 10, while the first material is still liquid or viscous.

Before arranging the molding tool 82 vertically above the substrate 10, the substrate 10 may be arranged in a housing 7 or in a mold 80. Many semiconductor module arrangements are arranged in housings 7, as is exemplarily illustrated in FIGS. 1 and 2. In such arrangements, the housing 7 itself may be filled with the first material. That is, after the first material has been poured into the housing 7 and after it has been cured (optional), the substrate 10 may remain in the housing 7. No separate mold is required in such cases.

However, if the casting compound 5 after curing the first material is a rigid molding compound and is sufficiently able to protect the substrate 10 from mechanical damage, a housing 7 may not be required. In such cases, the substrate 10 may be arranged in a mold 80 (see, e.g., FIGS. 3 and 4). The first material may be poured into the mold 80, with the substrate 10 arranged therein. The mold 80 prevents the first material from flowing off the substrate 10 until it has been cured. Once the first material has been cured, the substrate 10 with the casting compound 5 formed thereon may be removed from the mold 80 (not specifically illustrated).

Pouring the first material on the substrate 10 may comprise forming a layer of the first material on the substrate 10, wherein a height of the layer of the first material in the vertical direction y essentially equals the height of the plurality of pins 4 and/or rivets 44 in the vertical direction y, as is exemplarily illustrated in FIGS. 3 and 4. In this way, the pins 4 and/or rivets remain easily accessible for electrical contacting.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a semiconductor module arrangement, the method comprising:
arranging a molding tool vertically above a substrate of the semiconductor module arrangement, wherein a plurality of pins and/or rivets is arranged on the substrate, wherein each of the plurality of pins and/or rivets has essentially a same height in a vertical direction perpendicular to the substrate, wherein the molding tool comprises a plurality of cover elements, the plurality of cover elements comprising a first subset of cover elements and a second subset of cover elements, wherein each cover element of the first subset of cover elements is arranged vertically above a different one of the plurality of pins and/or rivets, and wherein the cover elements of the second subset of cover elements are not arranged vertically above any pin or rivet;
pressing each cover element of the first subset of cover elements on the respective pin or rivet; and
pouring a first material on the substrate, thereby covering the substrate and enclosing each of the plurality of pins and/or rivets, wherein the first material is prevented from covering a top surface of each of the plurality of pins and/or rivets by the respective cover elements of the first subset of cover elements.

2. The method of claim 1, wherein pressing each cover element of the first subset of cover elements on the respective pin or rivet comprises moving the molding tool together with the plurality of cover elements towards the substrate.

3. The method of claim 1, wherein pressing each cover element of the first subset of cover elements on the respective pin or rivet comprises individually moving the cover elements of the first subset towards the substrate.

4. The method of claim 1, further comprising curing the first material.

5. The method of claim 1, further comprising removing the molding tool after pouring the first material on the substrate.

6. The method of claim 1, further comprising, before arranging the molding tool vertically above a substrate, arranging the substrate in a housing or in a mold.

7. The method of claim 1, wherein pouring the first material on the substrate comprises forming a layer of the first material on the substrate, and wherein a height of the layer of the first material in the vertical direction essentially equals the height of the plurality of pins and/or rivets in the vertical direction.
